(19) United States
(12) Patent Application Publication
(10) Pub. No.: US 2008/0251915 A1
(43) Pub. Date: Oct. 16, 2008

(54) Structure of semiconductor chip and package structure having semiconductor chip embedded therein

(75) Inventors: Shih-Ping HSU, Hsinchu (TW); Shang-Wei Chen, Hsinchu (TW); Kan-Jung Chia, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/081,319

(22) Filed: Apr. 15, 2008

(30) Foreign Application Priority Data
Apr. 16, 2007 (TW) 096113324

(51) Int. Cl. H01L 23/498

(52) U.S. Cl. 257/737; 257/E23.068

(57) ABSTRACT

A semiconductor chip is disclosed, which comprises a chip having an active surface; plural electrode pads disposed on the active surface of the chip; a first passivation layer disposed on the chip, which has openings corresponding to the electrode pads to expose the electrode pads, wherein the first passivation layer is made of a material having high alkali resistance and low coefficient of elasticity; and plural metal bumps disposed in the openings of the first passivation layer. Therefore, as forming the metal bumps by a chemical deposition technique, the damage to the passivation layer can be prevented. Besides, as the semiconductor chip is embedded in a package structure, the problem of delamination occurred due to the mismatch in the coefficients of thermal expansion of the semiconductor chip and the dielectric layers can be avoided. Accordingly, the yield of the package structure having the semiconductor chip embedded therein can be improved.

### BACKGROUND OF THE INVENTION

1. Field of the Invention

The present invention relates to a semiconductor chip and a package structure having a semiconductor chip embedded therein, and, more particularly, to a semiconductor chip having plural metal bumps which are formed on the electrode pads by chemical deposition technique and a package structure having a semiconductor chip embedded therein.

2. Description of Related Art

As the electronic industry develops rapidly, researches move towards electronic devices with multifunction and high efficiency. Hence, circuit boards with many active and passive components and circuit connections thereon have been transformed from single-layered boards to multiple-layered boards so that the requirements such as integration and miniaturization in semiconductor package substrate can be met. Furthermore, interlayer connection technique is also applied in this field to expand circuit layout space in a limited circuit board and to meet the demand of the application of high-density integrated circuits.

For manufacturing conventional semiconductor package structures, a semiconductor chip is mounted on the top surface of a substrate first, and then connected thereto by wire bonding. Alternatively, the semiconductor chip is connected with the substrate by flip chip technique. Subsequently, solder balls are disposed on the bottom surface of the substrate and electrically connected to a printed circuit board. However, even though the purpose of high quantity pin counts can be achieved through the method illustrated above, the electrical performance of a device operated in high frequency or at high speed can be unstable or limited due to the long paths of conductive circuits. Moreover, the complexity of the manufacturing process and the manufacturing cost are relatively increased because many connective interfaces are required for conventional semiconductor package structures.

Currently, a package structure having a semiconductor chip embedding therein is enthusiastically developed because the semiconductor chip can electrically connects to an electric device outside the package structure through a short transmission-path of current so as to reduce the signal loss and distortion, and improve the operation ability in high frequency.

FIG. 1 shows a conventional package structure having a semiconductor chip embedding therein, which comprises: a core board 11 having a cavity; a chip 12 disposed in the cavity, wherein a plurality of electrode pads 13 are formed on an active surface of the chip 12; a passivation layer 14 disposed on the chip 12, wherein the passivation layer 14 having plural openings corresponding to the electrode pads 13; a plurality of metal bumps 15 disposed on the electrode pads 13; a built-up structure 16 disposed on the surface of the core board 11 and the active surface of the chip 12; a solder mask 17 disposed on the surface of the built-up structure 16, wherein the solder mask 17 has plural openings corresponding to a circuit layers 16b of the built-up structure 16 as conductive pads; and a plurality of solder balls 18 disposed on the conductive pads to connect with a printed circuit board. Besides, the built-up structure 16 is mainly composed of dielectric layers 16a and circuit layers 16b. The structure of the built-up structure is well known in this field and, therefore, the detail of a built-up process is not described herein.

In the processes for manufacturing the package structure having a semiconductor chip embedding therein, damages to the electrode pads 13 disposed on the surface of the chip 12 are frequently caused due to, for example, the laser drilling process of the dielectric layers 16a. Accordingly, it is necessary to dispose the metal bumps 15 on the surface of the electrode pads 13 to avoid the damage to the chip 12 embedded in the package structure.

The major methods for forming the metal bumps 15 are electroplating methods and electroless plating methods. Among them, chemical deposition technique, one of the electroless plating methods, is most economical. Unfortunately, chemical deposition technique is preceded by using strong alkaline solution that may destroy or peel off the passivation layer 14 so as to cause damages to the surface of the silicon base of the chip 12. So far, in the application in industry, the passivation layer 14 is mostly made of benzocyclobutene (BCB) or polyimide (PI) for protecting the silicon base of the chip 12 and electric isolation. Both of these materials are corroded by strong alkaline solution.

In addition, the mismatch in the coefficients of thermal expansion of the dielectric layers 16a and the chip 12 leads to delamination between the dielectric layers 16a and the chip 12 after the dielectric layers 16a is formed on the core board 11 having the chip 12 embedded therein.

Therefore, it is desirable to provide a new material of the passivation layer 14 to satisfy the need of reducing the damage of the passivation layer 14 and the delamination between the dielectric layers 14 and the chip 12 so as to improve the yield of the package structure.

### SUMMARY OF THE INVENTION

The present invention provides a semiconductor chip having one passivation layer made of an alkali resistance material or more than one passivation layers wherein at least one passivation layers is made of an alkali resistance material. Accordingly, as forming metal bumps on a chip by chemical deposition technique using strong alkaline solution, the passivation layer can resist the strong alkaline solution to protect the chip there under from damage. In addition, as the material used for the passivation layer has low coefficient of elasticity, the delamination between a chip and a built-up structure due to the mismatch in the coefficients of thermal expansion can be prevented.

One aspect of the present invention provides a semiconductor chip comprising: a chip having an active surface; a plurality of electrode pads disposed on the active surface of the chip; a first passivation layer disposed on the chip, which has a plurality of openings corresponding to the location of the electrode pads so as to expose the electrode pads, wherein the first passivation layer is made of a material having high alkali resistance and low coefficient of elasticity; and a plurality of metal bumps disposed in the openings of the first passivation layer.

In the semiconductor chip of the present invention, the material of the first passivation layer is not particularly limited, as long as the material of the first passivation layer has high alkali resistance, low coefficient of elasticity and good electric isolation. Preferably, the first passivation layer is made of siloxane polymer.

Moreover, the semiconductor chip of the present invention can further comprises a second passivation layer disposed between the first passivation layer and the chip, wherein the second passivation layer has a plurality of openings corresponding to the location of the electrode pads so as to expose the electrode pads. The material of the second passivation layer is not limited. Preferably, the second passivation layer is made of benzocyclobutene (BCB), silicon nitride, or polyimide (PI). In one case, the semiconductor chip can be manufactured by the steps of providing a commercial semiconductor chip, which comprises a passivation layer made of BCB or PI (i.e. the second passivation layer), produced in current industry; forming another passivation layer made of a material with high alkali resistance and low coefficient of elasticity (i.e. the first passivation layer) on the second passivation layer; and then forming the metal bumps by chemical deposition technique. In addition, as the material used for the passivation layer has low coefficient of elasticity, the delamination between a chip and a built-up structure due to the mismatch in the coefficients of thermal expansion can be prevented.

In the semiconductor chip of the present invention, the surface of the metal bumps is equal to, higher than, or lower than that of the first passivation layer. Preferably, the metal bumps protrude the surface of the first passivation layer.

In the semiconductor chip of the present invention, the material of the metal bumps is not limited. Preferably, the material of the metal bumps is selected from the group consisting of nickel/palladium/gold/copper, nickel/gold/copper, nickel/copper, and nickel/palladium/copper.

In the semiconductor chip of the present invention, the material of the electrode pads is not limited. Preferably, the material of the electrode pads is selected from the group consisting of aluminum or copper.

Another aspect of the present invention provides a package structure having a semiconductor chip embedded therein for preventing a passivation layer of a semiconductor chip from being corroded by a strong alkaline solution used in a chemical deposition process for forming metal bumps. Accordingly, the yield of package structures can be improved.

The package structure having a semiconductor chip embedded therein, comprising: a core board having a cavity; a semiconductor chip disposed in the cavity, which comprises a chip, a plurality of electrode pads, a first passivation layer and a plurality of metal bumps, wherein the chip has an active surface, the electrode pads are disposed on the active surface, the first passivation layer, disposed on the chip, has plural openings corresponding to the location of the electrode pads so as to expose the electrode pads, the metal bumps are disposed in the openings of the first passivation layer, and the first passivation layer is made of a material with high alkali resistance and low coefficient of elasticity; and a built-up structure disposed on the core board and the active surface of the chip, wherein the built-up structure electrically connects with the metal bumps of the semiconductor chip.

In the package structure of the present invention, the material of the first passivation layer is not particularly limited, as long as the material of the first passivation layer has high alkali resistance, low coefficient of elasticity and good electric isolation. Preferably, the first passivation layer is made of siloxane polymer.

Moreover, the semiconductor chip of the package structure can further comprises a second passivation layer disposed between the first passivation layer and the chip, wherein the second passivation layer has a plurality of openings corresponding to the location of the electrode pads so as to expose the electrode pads. The material of the second passivation layer is not limited. Preferably, the second passivation layer is made of benzocyclobutene (BCB), silicon nitride, or polyimide (PI). In one case, the semiconductor chip can be manufactured by the steps of providing a commercial semiconductor chip, which comprises a passivation layer made of BCB or PI (i.e. the second passivation layer), produced in current industry; forming another passivation layer made of a material with high alkali resistance and low coefficient of elasticity (i.e. the first passivation layer) on the second passivation layer; and then forming the metal bumps by chemical deposition technique. As the material used for the passivation layer has low coefficient of elasticity, the delamination between the commercial semiconductor chip and the built-up structure due to the mismatch in the coefficients of thermal expansion can be prevented.

In the semiconductor chip of the package structure, the surface of the metal bumps is equal to, higher than, or lower than that of the first passivation layer. Preferably, the metal bumps protrude the surface of the first passivation layer.

In the semiconductor chip of the package structure, the material of the metal bumps is not limited. Preferably, the material of the metal bumps is selected from the group consisting of nickel/palladium/gold/copper, nickel/gold/copper, nickel/copper, and nickel/palladium/copper.

In the semiconductor chip of the package structure, the material of the electrode pads is not limited. Preferably, the material of the electrode pads is selected from the group consisting of aluminum or copper.

In the package structure of the present invention, the built-up structure comprises a plurality of dielectric layers, a plurality of circuit layers and a plurality of conductive vias, in which the circuit layers and the dielectric layers are laminated alternatively, the conductive vias penetrate the dielectric layers to electrically connect with the circuit layers and the electrode pads or the circuit layers under the dielectric layers.

In addition, the package structure of the present invention may further comprises a solder mask disposed on the surface of the built-up structure, wherein the solder mask has plural openings to expose part of the circuit layers as conductive pads. The solder mask can be made of a polymer with photosensitive and dewetting properties

Furthermore, the package structure of the present invention may further comprises a plurality of solder balls disposed on the conductive pads. The solder balls can be made of a material selected from a group consisting of lead, tin, silver, copper, bismuth, antimony, zinc, nickel, magnesium, indium, tellurium, gallium, and a alloy thereof.

Other objects, advantages, and novel features of the invention will become more apparent from the following detailed description when taken in conjunction with the accompanying drawings.

### BRIEF DESCRIPTION OF THE DRAWINGS

FIG. 1 shows a conventional package structure having a semiconductor chip embedding therein in a cross-sectional view;

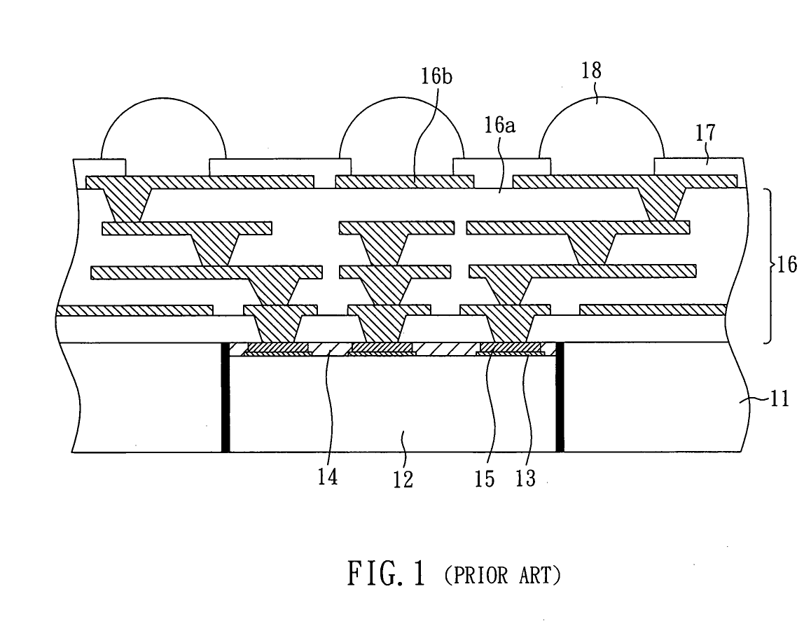

FIG. 2 shows a semiconductor chip in a cross-sectional view according to one preferred embodiment of the present invention;

FIG. 3 shows a package structure having a semiconductor chip embedded therein in a cross-sectional view according to one preferred embodiment of the present invention; and

FIG. 4 shows a semiconductor chip in a cross-sectional view according to the other preferred embodiment of the present invention.

### DETAILED DESCRIPTION OF THE PREFERRED EMBODIMENT

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

### Embodiment 1

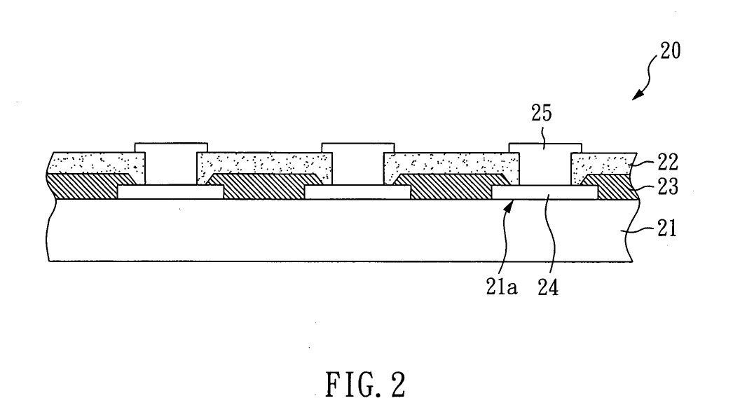

With reference to FIG. 2, there is shown a semiconductor chip in a cross-sectional view. The semiconductor chip in this embodiment is obtained by processing a conventional semiconductor chip, of which a second passivation layer 23 is made of BCB or PI, produced in current industry. The process for forming a semiconductor chip is illustrated as follows.

Referring to FIG. 2, a conventional semiconductor chip comprising a chip 21, a plurality of electrode pads 24, and a second passivation layer 23 is prepared. In FIG. 2, the chip 21 has an active surface 21a, and the electrode pads 24 are disposed on the active surface 21a. Generally, the material of the electrode pads 24 is aluminum or copper. The second passivation layer 23, disposed on the chip 21, has plural openings corresponding to the location of the electrode pads 24 so as to expose the electrode pads 24 of the chip 21. In this embodiment, the second passivation layer 23 is made of BCB for protecting the active surface 21 a of the chip 21 and providing electric isolation.

Then, a first passivation layer 22 is formed on the second passivation layer 23. Meanwhile, the first passivation layer 22 has plural of openings corresponding to the location of the electrode pads 24 so as to expose the electrode pads 24 of the chip 21.

Subsequently, a plurality of metal bumps 25 are formed in the openings of the first passivation layer 22 by means of chemical deposition technique. Accordingly, the damages to the surface of the electrode pads 24 caused by, for example, the laser drilling process of dielectric layers 31 proceeded later can be prevented.

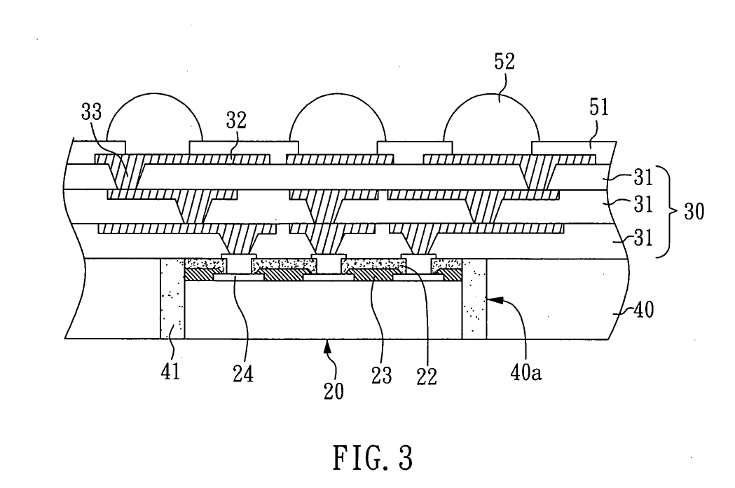

After the semiconductor chip, as shown in FIG. 2, formed by the aforementioned process is obtained, the semiconductor chip can be embedded in a package structure. FIG. 3 shows a package structure having a semiconductor chip embedded therein in a cross-sectional view. Referring to FIG. 3, the package structure comprises a core board 40, a semiconductor chip 20, a built-up structure 30, a solder mask 51, and a plurality of solder balls 52. The process for forming the package structure is illustrated as follows.

First, the semiconductor chip 20 obtained from the aforementioned process is embedded in a cavity 40a of the core board 40. Meanwhile, the cavity 40a is filled with a resin 41 to fix the semiconductor chip 20 embedded in the core board 40.

Further, the built-up structure 30 is formed on the core board 40 and the active surface 21 a of the semiconductor chip 20 to electrically connect with the electrode pads 24 of the semiconductor chip 20. With reference to FIG. 3, the built-up structure 30 includes a plurality of dielectric layers 31, a plurality of circuit layers 32 and a plurality of conductive vias 33. The circuit layers 32 and the dielectric layers 31 are laminated alternatively, the conductive vias 33 penetrate the dielectric layers 31 to electrically connect with the electrode pads 24 or the circuit layers 32 under the dielectric layers 31. It is important that the first passivation layer 22 has to be made of a material with high alkali resistance and low coefficient of elasticity so that the stress between the chip 21 and the dielectric layers 31 can be eliminated and the occurrence of delamination can be prevented. The material of the first passivation layer 22 in this embodiment is siloxane polymer.

Finally, the solder mask 51 and the solder balls 52 are formed on the built-up structure 30 in sequence. Accordingly, the package structure having the semiconductor chip embedded therein in this embodiment is obtained.

### Embodiment 2

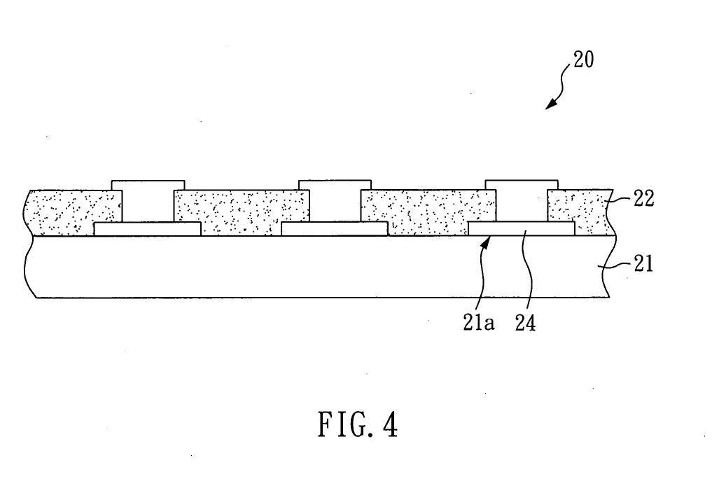

FIG. 4 shows a semiconductor chip 20 in a cross-sectional view. The structure of the semiconductor chip 20 of this embodiment, as shown in FIG. 4, is the same as that of embodiment 1, as shown in FIG. 2, except that the semiconductor chip 20 of this embodiment has only one passivation layer (i.e. the first passivation layer 22).

In above embodiments, the first passivation layer 22 made of a material with high alkali resistance and low coefficient of elasticity is formed on the chip 21 of the semiconductor chip 20. Therefore, as forming metal bumps 25 on the chip 21 by chemical deposition technique using strong alkaline solution, the first passivation layer 22 can resist the strong alkaline solution to protect the chip 21 there under from damage. In addition, as the material used for the first passivation layer 22 has low coefficient of elasticity, the delamination between the chip 21 and a built-up structure 30 due to the mismatch in the coefficients of thermal expansion can be prevented. Accordingly, the yield and the reliability of the package structure having the semiconductor chip embedded therein in the above embodiments can be increased.

Although the present invention has been explained in relation to its preferred embodiment, it is to be understood that many other possible modifications and variations can be made without departing from the scope of the invention as hereinafter claimed.

What is claimed is:

1. A semiconductor chip comprising:
a chip having an active surface;
a plurality of electrode pads disposed on the active surface of the chip;
a first passivation layer disposed on the chip, which has a plurality of openings corresponding to the location of the electrode pads so as to expose the electrode pads, wherein the first passivation layer is made of a material having high alkali resistance and low coefficient of elasticity; and
a plurality of metal bumps disposed in the openings of the first passivation layer.

2. The semiconductor chip as claimed in claim 1, wherein the first passivation layer is made of siloxane polymer.

3. The semiconductor chip as claimed in claim 1, further comprising a second passivation layer disposed between the first passivation layer and the chip, wherein the second passivation layer has a plurality of openings corresponding to the location of the electrode pads so as to expose the electrode pads.

4. The semiconductor chip as claimed in claim 1, wherein the metal bumps are formed by chemical deposition.

5. The semiconductor chip as claimed in claim 1, wherein the surface of the metal bumps is equal to, higher than, or lower than that of the first passivation layer.

6. The semiconductor chip as claimed in claim 1, wherein the material of the metal bumps is selected from the group consisting of nickel/palladium/gold/copper, nickel/gold/copper, nickel/copper, and nickel/palladium/copper.

7. A package structure having a semiconductor chip embedded therein, comprising:
a core board having a cavity;
a semiconductor chip disposed in the cavity, which comprises a chip, a plurality of electrode pads, a first passivation layer and a plurality of metal bumps, wherein the chip has an active surface, the electrode pads are disposed on the active surface, the first passivation layer, disposed on the chip, has plural openings corresponding to the location of the electrode pads so as to expose the electrode pads, the metal bumps are disposed in the openings of the first passivation layer, and the first passivation layer is made of a material with high alkali resistance and low coefficient of elasticity; and
a built-up structure disposed on the core board and the active surface of the chip, wherein the built-up structure electrically connects with the metal bumps of the semiconductor chip.

8. The package structure as claimed in claim 7, wherein the first passivation layer is made of siloxane polymer.

9. The package structure as claimed in claim 7, further comprising a second passivation layer disposed between the first passivation layer and the chip, wherein the second passivation layer has a plurality of openings corresponding to the location of the electrode pads so as to expose the electrode pads.

10. The package structure as claimed in claim 7, wherein the metal bumps is formed by chemical deposition.

11. The package structure as claimed in claim 7, the surface of the metal bumps is equal to, higher than, or lower than that of the first passivation layer.

12. The package structure as claimed in claim 7, wherein the material of the metal bumps is selected from the group consisting of nickel/palladium/gold/copper, nickel/gold/copper, nickel/copper, and nickel/palladium/copper.

13. The package structure as claimed in claim 7, wherein the built-up structure comprises a plurality of dielectric layers, a plurality of circuit layers and a plurality of conductive vias, in which the circuit layers and the dielectric layers are laminated alternatively, the conductive vias penetrate the dielectric layers to electrically connect with the circuit layers and the electrode pads or the circuit layers under the dielectric layers.

14. The package structure as claimed in claim 13, further comprising a solder mask disposed on the surface of the built-up structure, wherein the solder mask has plural openings to expose part of the circuit layers as conductive pads.

15. The package structure as claimed in claim 13, wherein the material of the solder mask is a polymer with photosensitive and dewetting properties.

16. The package structure as claimed in claim 14, further comprises a plurality of solder balls disposed on the conductive pads.

17. The package structure as claimed in claim 16, wherein the solder balls is made of a material selected from a group consisting of lead, tin, silver, copper, bismuth, antimony, zinc, nickel, magnesium, indium, tellurium, gallium, and a alloy thereof.
